(19) United States
(12) Patent Application Publication
(10) Pub. No.: US 2007/0285117 A1
(43) Pub. Date: Dec. 13, 2007

(54) CURRENT ABNORMALITY DETECTION SYSTEM AND METHOD FOR SHUNT MOTORS

(75) Inventor: Hiroshi Hirano, Shizuoka-ken (JP)

Correspondence Address: ERNEST A. BEUTLER, ATTORNEY AT LAW, 10 RUE MARSEILLE, NEWPORT BEACH, CA, 92660, US

(73) Assignee: KABUSHIKI KAISHA MORIC, Mori-machi (JP)

(21) Appl. No.: 11/161,441

(22) Filed: Aug. 3, 2005

(30) Foreign Application Priority Data
Aug. 23, 2004 (JP) 2004-242217

(51) Int. Cl. G01R 31/34

(52) U.S. Cl. 324/772

(57) ABSTRACT

A current abnormality detection system and method for shunt motors having a battery as a power source and an armature coil and a field coil controlled by an armature drive circuit and a field drive circuit formed in a controller, each drive circuit having a respective current sensor, An abnormal condition is determined when no less than a specified time has elapsed in a condition in which the difference between a current command value of the field coil with respect to the amount of current-flow in the armature coil and the current detection value of the field coil exceeds a given tolerance value.

### BACKGROUND OF THE INVENTION

This invention relates to a current abnormality detection system for motors and specifically in a DC shunt motor used for a drive source of an electric motor-driven vehicle such as a golf car, for detecting abnormality in current control mechanisms of the motor.

Hitherto, as shown in Japanese Published Application JP-A-Hei 10-309005, an electric motor-driven vehicle such as a golf car has been proposed in which a battery is provided as a power source for a DC shunt-wound type motor having an armature coil and a field coil.

In the shunt motor, the amount of current supply to the armature coil and that to the field coil are controlled separately according to a map established corresponding to the motor characteristics. To explain this generally, FIGS. 4 and 5 are graphs of the armature current and the field current applied in this invention as will be described in more detail later. FIG. 4 shows a command value of a proper amount of current supply to the armature coil in response to the accelerator opening by the depression of an accelerator pedal. FIG. 5 is an armature current (Ia)-field current (If) map, showing the amount of current supply to a field coil required for a motor to be operated at maximum efficiency with minimum power consumption in response to the amount of current-flow in the armature coil. As a result, when a current of a given value is supplied to the field coil in response to the current of the armature coil according to the Ia-If map the desired torque is generated in by motor, and the vehicle movement can be controlled in response to various operating conditions.

To perform the described current control, an armature drive circuit for controlling the armature coil and a field drive circuit for controlling the field coil are provided in a controller. In addition current sensors are provided between the armature coil and the armature drive circuit and between the field coil and the field drive circuit, respectively to detect the amount of current actually flowing.

How this is done conventionally in accordance with the prior art will now be described by reference to the flow chart of FIG. 1. First at the step U1 a current command value to the armature coil is calculated in response to the amount of depression of the accelerator pedal. Then the current values of the armature coil and the field coil are measured by respective current sensors at the step U2. From this a current command value to the field coil is calculated at the Step U3 according to the Ia-If map in response to the current value of the armature coil detected at the step U2.

Next at the step U4 a calculation is performed in which each of the current command values calculated at the steps U1 and U3 for conversion to a value of the Duty ratio by PWM control. Finally a feedback control is performed at the step U5 based on the current values detected by the current sensors on the armature side and the field side, using the command values of the step U4 as target values. Therefore, the command values are updated further in response to the differences between the detected current values and the command values.

This procedure is repeated continuously in cycles at regular intervals of a given time. Therefore, the current values are detected at all times by the current sensors provided on the armature side and the field side. The current detection value at the step U2 is zero in the first cycle.

With such a conventional current control, when current values in the armature coil and the field coil exceed given ones and become excessive, that is, for example, when the armature current is greater than 300 A and the field current is greater than 20 A, it is judged to be abnormal and energization is stopped to prevent thermal damage to the controller or other components. That is, when the field current and the armature current are detected, and when the current values exceed those set out above, it is judged to be abnormal.

However, even when the field current is no larger than that deemed excessive, if it exceeds a proper field current according to the Ia-If map, that is if it falls within the hatched portion A of FIG. 5, the field current exceeds that on the line of the Ia-If map, the efficiency of the motor is decreased. However if the current value is no larger than the one of the excessive current (field current of 20 A) which is judged to be abnormal, the motor operation is continued in the conventional system. Thus no means has been provided by the prior art to judge which such a condition to be abnormal.

Such a situation could be caused by any of failure in the current sensor or the controller, in case of abnormal wiring, or when the motor is replaced by the one of a different characteristic. In these cases, the motor will be operated with a field current greater than the command value, thus lowering operation efficiency of the motor and resulting in wasteful battery consumption.

Therefore it is a principal object of this invention is to provide a current abnormality detection system and method for shunt motors for continuously checking whether predetermined proper field current is flowing with respect to the detected amount of current-flow in the armature coil of a shunt motor.

### SUMMARY OF THE INVENTION

A first feature of the invention is adapted to be embodied in current abnormality detection system for shunt motors having a battery as a power source and an armature coil and a field coil controlled by an armature drive circuit and a field drive circuit formed in a controller. Each drive circuit is provided with a current sensor. The condition is judged to be abnormal when no less than a specified time has elapsed in a condition in which the difference between a current command value of the field coil with respect to the amount of current-flow in the armature coil and the current detection value of the field coil exceeds a given tolerance value.

Another feature of the invention is adapted to be embodied in a method for determining current abnormality in shunt motors having a battery as a power source and an armature coil and a field coil controlled by an armature drive circuit and a field drive circuit formed in a controller. The method comprises sensing the current in each of the coils. Judging the operation to be abnormal when no less than a specified time has elapsed in a condition in which the difference between a current command value of the field coil with respect to the amount of current-flow in the armature coil and the current detection value of the field coil exceeds a given tolerance value.

### BRIEF DESCRIPTION OF THE DRAWINGS

FIG. 1 is a block diagram of a prior art control routine for determining abnormal operation of a shunt motor powering an electric motor driven vehicle.

FIG. 2 is a top plan view of an electric powered vehicle in the example of a golf cart constructed and operated in accordance with the invention.

FIG. 3 is a block diagram of a drive controlling device for a golf car in accordance with the invention.

FIG. 4 is a graphical view of the relationship between the position of the accelerator pedal of the vehicle and the armature coil command value.

FIG. 5 is a graphical view showing the desired relationship between the armature current and the field current and the areas where undesired operation has occurred.

FIG. 6 is a block diagram showing the control routine in accordance with the invention.

FIG. 7 is a flow chart showing control routine in accordance with the invention.

### DETAILED DESCRIPTION

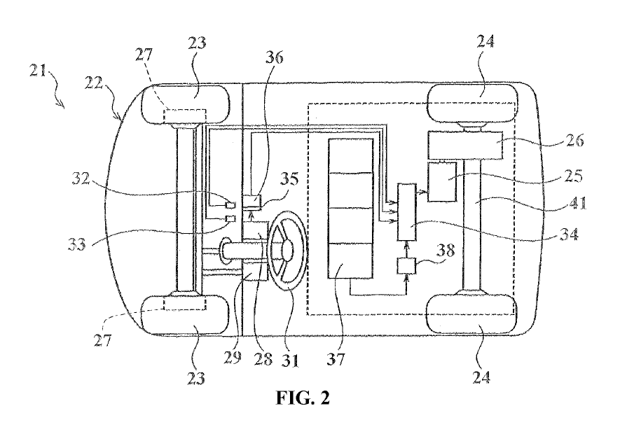

Referring now in detail to the drawings and initially to FIG. 2, an electrically powered vehicle such as a golf cart, as an example of vehicle with which the invention may be practiced is identified generally by the reference numeral 21. This golf cart 21 is provided with a body, frame 22 that rotatably supports in any desired manner paired front wheels 23 and rear wheels 24. In the illustrated embodiment, the rear wheels 24 are driven by a shunt type electric motor 25 through a transmission 26. Associated with some or all of the wheels 23 and 24 (only the front wheels 23 in the illustrated embodiment) are brakes 27 of any desired type.

An operator may be seated on a suitable seat (neither of which are shown) behind an accelerator pedal 28, for controlling the speed of the electric motor 25, a brake pedal 29, for operating the wheel brakes 27, and a steering wheel 31, for steering the front wheels 23 in any desired manner.

Also juxtaposed to the operator's position is a main switch 32, and a direction control switch 33, for controlling the direction of travel of the golf cart 21 by controlling the direction of rotation of the motor 25. The main switch 32 and the direction control switch 33 are connected to a controller 34. Operation of the accelerator pedal 28 is transmitted to an on off pedal switch 35 and an accelerator opening degree sensor 36 connected to the controller 34, to send on or off state of the accelerator 28 and its degree of opening to the controller 34.

A plurality of batteries 37 (48 V in total, for example) as power sources are mounted suitably on the body frame 22 and are connected through a relay 38 to the controller 34.

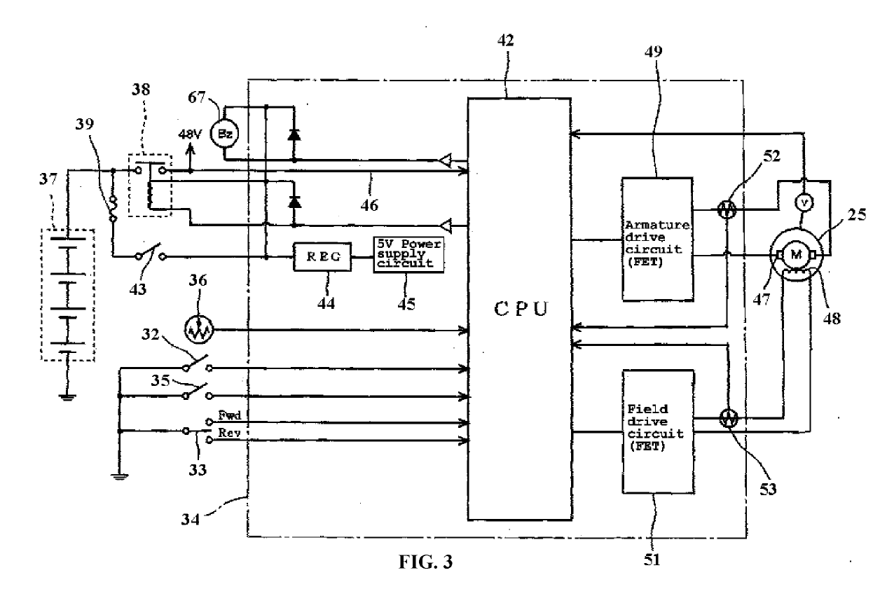

The electrical supply for the motor will now be described by reference to FIG. 3 which is a block circuit diagram of the golf cart 21 of FIG. 2. As will be seen, the source voltage for the motor 25 of shunt winding type that drives the golf cart 21 and for the controller 34 is supplied from the battery 37. The source voltage sent from the battery 37 is supplied to a CPU 42 that has a memory, a control circuit and so forth via the relay 38.

The source voltage of the battery 37 is supplied to the controller 34 via a fuse 39 and a control switch 43. The control switch 43 is used to stop the power supply to the controller 34 as the need arises, so as to stop an operation of an automatic brake circuit when, for example, a traction running or the like is made. The source voltage of 48V, for example, of the battery 37 is converted to 5V by a voltage lowering regulator 44 and a power supply circuit 45 in the controller 34, and is supplied to respective arithmetic circuits and drive circuits in the controller 34.

An analog amount of an actual voltage of the battery 37 is converted in the controller 34 to a digital amount of 0-5V which is suitable for arithmetic processing, and is inputted to the CPU 42 through a battery voltage AD input line 46 and via an interface (not shown). That is, the battery voltage is initially 48V; however, it goes down gradually or in response to its condition during its time and nature of use, depending on the use conditions and the deterioration condition of the battery 37. Thus, in order to make the arithmetic processing for the control based upon the battery voltage, an analog amount of, for example, 0-50V is converted to a digital amount of 0-5V and is inputted to the CPU 42.

Signals from the main switch 32, the pedal switch 35, the direction change switch 33, the accelerator opening sensor 36 and so forth are inputted to the CPU 42. The CPU 42 drives and controls the motor 25 based upon those signals.

As has been noted, the motor 25 of shunt winding type and has an armature coil 47 and a field coil 48 which are connected to an armature drive circuit 49 and a field drive circuit 51, respectively. Each of the armature drive circuit 49 and the field drive circuit 51 is formed with a plurality of FETs. Command currents calculated by an armature PWM arithmetic circuit and a field PWM arithmetic circuit (not shown) in the CPU 42 are impressed to the armature coil 47 and the field coil 48 via the armature drive circuit 49 and the field drive circuit 51, respectively.

An armature current (Ia) and a field current (If) are applied in accordance with commands given by PWM signals that indicate ratios of drive pulse widths. The field current is calculated based upon an Ia-If map of FIG. 5, as has been previously mentioned and which is previously programmed in accordance with a motor characteristic. This Ia-If map designates the field current amount at which the motor 25 is driven with the maximum efficiency relative to the armature current, and is stored in the memory (not shown) in the CPU 42.

Current sensors 52, 53 are disposed between the armature drive circuit 49 and the field drive circuit 51 and the armature coil 47 and the field coil 48 of the motor 53, respectively. Those sensors detect currents that actually flow through the armature coil 47 and the field coil 48. The command signals for driving the motor 25 and coming from the CPU 42 are feedback-controlled by those detected signals. Thereby, the currents flowing through the armature coil 47 and the field coil 48 of the motor 25 are accurately controlled, and cause the motor 25 generate the desired amount of torque corresponding to the amount of depression of the accelerator pedal 28.

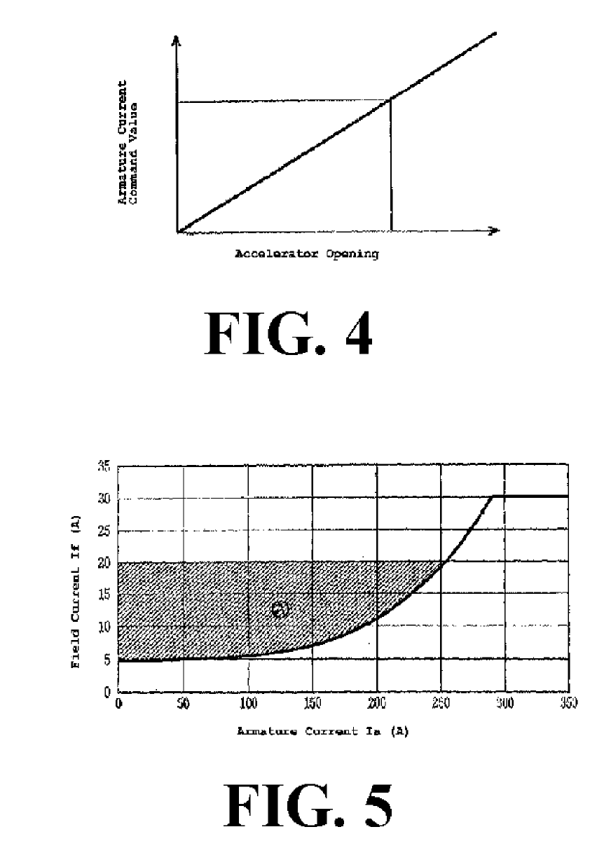

As previously mentioned in reference to FIG. 4, a command value of the armature current is calculated in response to the accelerator opening, and the field current is calculated according to the Ia-If map of FIG. 5 in response to the armature current. The Ia-If map is programmed in advance corresponding to the motor characteristics for each motor and stored in a memory (not shown) in the CPU 42. In the CPU 42, a field current command value is calculated in response to the armature current based on this map. An accelerator-armature current map for calculating the armature current may be prepared in advance based on the characteristics of FIG. 4 and stored in a memory.

As shown in FIG. 4, the proper amount of current supply to the armature coil 47, or the current command value, is established in response to the accelerator opening. When a driver steps on the accelerator pedal 28, an armature current required for a given vehicle speed is calculated according to the characteristics.

FIG. 5 is an Ia-If map, showing the current value of the field coil 48 when the motor 25 is operated at maximum efficiency with the smallest power consumption, with respect to the current value of the armature coil 47. At this time, the value of the armature current depends on the actual detection value detected by an ammeter 52 on the armature. As a result, compared with the current command value calculated according to the characteristics of FIG. 4, the value is usually decreased by the amount of drop due to load such as the vehicle or its running conditions.

Currents of given values are supplied to the armature coil 47 and the field coil 48, based on the calculation result in the CPU 42. Thus, a given torque is generated in the motor 25 and movements can be controlled to various operating conditions of the motor-driven vehicle.

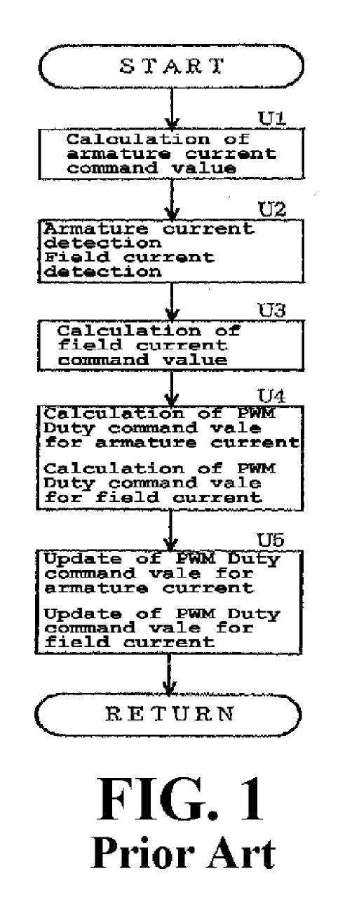

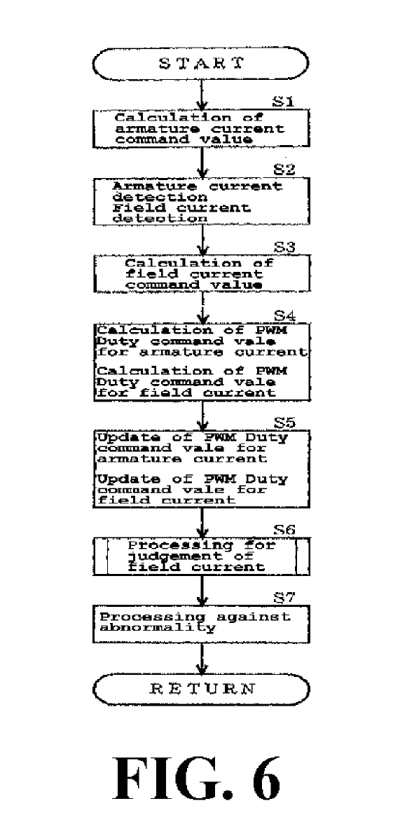

Referring now to FIG. 6, as already noted, this is a flowchart showing a procedure of the current control according to this invention, which is processed by the CPU 42. Details of the processing of steps S1-S5 are the same as those of steps U1-U5 in the foregoing conventional system shown in FIG. 1. Thus at the step S1: a current command value to the armature coil 47 is calculated according to the characteristics of FIG. 4 in response to the amount of depression of the accelerator pedal 28.

Then at the step S2: the current values of the armature coil 47 and the field coil 48 are detected by the current sensors 52, 53.

From this detection, a current command value to the field coil 48 is calculated according to the Ia-If map of FIG. at the step S35 in response to the current value of the armature coil 47 detected at the step S2.

Then at the step S4 a calculation is performed in which each of the current command values (in A) calculated at the steps S1 and S3 is converted to a value of the Duty ratio by PWM control.

The final prior art method is completed at the step S5 where feedback control is performed based on the current values detected from the armature coil 47 and the field coil 48, using the command values of the step S4 as target values. Therefore, the command values are updated further in response to the differences between the detected current values and the command values.

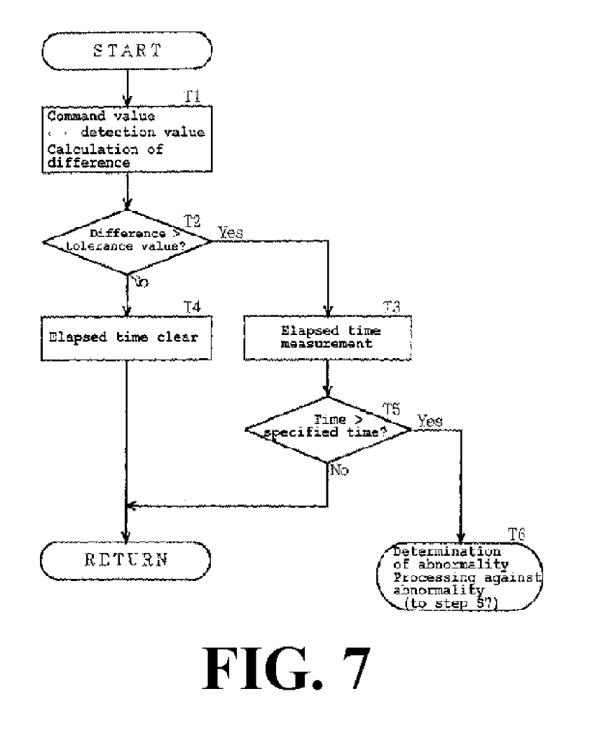

In accordance with the invention, at the step S6 a processing is performed for current abnormality judgment as will be described later by reference to FIG. 7.

When a judgment is made at the step S6 that there is an abnormality, processing against abnormality is performed at the step S7. Current supply is usually stopped to stop the motor-driven vehicle. In addition, a warning may be issued through a warning sound, a warning light and the like such as a buzzer 67 (FIG. 3). When processing against abnormality is performed, data on the history of abnormality is recorded in the controller 34. If no abnormality is detected at the step S6, the step S7 is skipped.

This procedure is repeated continuously in cycles at regular intervals of a given time during energization.

Referring now to FIG. 7, as has been noted, this is a flowchart showing the procedure of the processing for the abnormality judgment of this invention, which shows details of the processing at the step S6 of FIG. 6. This process begins at the step T1 where the difference between the command value of the field current according to the Ia-If map and the value of the field current detected by the current sensor 25 is determined. Then at the step T2 it is judged whether or not the difference at the step T1 is larger than a predetermined tolerance value, established in advance according to the Ia-If map of FIG. 5.

If the difference exceeds the tolerance value, at the step T3, the time elapsed after the difference exceeded the tolerance value is measured at the step T5. This is because there is a delay between the time the current command value is calculated and the time the current is actually supplied and detected. This prevents misjudgment of the abnormality due to an instantaneous large difference when an abrupt change in the current command value has happened (for example during acceleration, deceleration and the like).

If the time at the step T3 does not exceed the predetermined time the program goes to the step T4 where the operation is judged to be normal and the timer is reset and the elapsed time is cleared. This is because if the elapsed time till the present time is not cleared, no elapsed time after the detection of abnormality can be measured accurately because the elapsed time has been counted when an abnormality is detected in the next flow.

Returning now to step T5 where it is judged whether or not the elapsed time measured at the step T3 is longer than a specified time as established in advance according to the response characteristics of the motor-driven vehicle. When the time during which the difference exceeds the tolerance value is shorter than the specified time, it is not judged to be abnormal and the program returns.

On the other hand if at the step T6 a time longer than the specified time is measured, it is judged to be abnormal and then, processing against abnormality at the step S7 of FIG. 6 is performed.

Since, as described above, the difference between the detection value of the field current and the command value according to the Ia-If map is examined continuously, a proper field current can be held in response to the armature current at all times. Therefore, the abnormality in the area A of FIG. 5 which has not been judged to be abnormal up to the present can be judged correctly.

Of course those skilled in the art will readily understand that the described embodiment is only of a exemplary form that the invention may take and that various changes and modifications may be made without departing from the spirit and scope of the invention, as defined by the appended claims.

What is claimed is:

1. A current abnormality detection system for shunt motors having a battery as a power source and an armature coil and a field coil controlled by an armature drive circuit and a field drive circuit formed in a controller, each drive circuit having a respective current sensor, determining an abnormal condition when no less than a specified time has elapsed in a condition in which the difference between a current command value of the field coil with respect to the amount of current-flow in the armature coil and the current detection value of the field coil exceeds a given tolerance value.

2. A current abnormality detection system for shunt motors as set forth in claim 1 wherein processing against abnormality is performed immediately after a judgment of abnormality is made.

3. A current abnormality detection system for shunt motors as set forth in claim 2, wherein when the processing against abnormality is performed, a history of abnormality is recorded in said controller.

4. A current abnormality detection method for shunt motors having a battery as a power source and an armature coil and a field coil controlled by an armature drive circuit and a field drive circuit formed in a controller comprising the steps of measuring the current flow in each of the coils, and determining the existence of an abnormal condition when no less than a specified time has elapsed in a condition in which the difference between a current command value of the field coil with respect to the amount of current-flow in the armature coil and the current detection value of the field coil exceeds a given tolerance value.

5. A current abnormality detection method for shunt motors as set forth in claim 4 wherein processing against abnormality is performed immediately after a judgment of abnormality is made.

6. A current abnormality detection system for shunt motors as set forth in claim 5, wherein when the processing against abnormality is performed, a history of abnormality is recorded.
